(19) United States
(12) Patent Application Publication
(10) Pub. No.: US 2020/0341050 A1
(43) Pub. Date: Oct. 29, 2020

(54) CURRENT DRIVER ARRAY TEST APPARATUS, TEST METHOD THEREOF, AND MICRO LIGHT EMITTING DIODE ARRAY TEST METHOD

(71) Applicant: Novatek Microelectronics Corp., Hsinchu (TW)

(72) Inventor: Sheng-Wen Hsiao, Changhua County (TW)

(73) Assignee: Novatek Microelectronics Corp., Hsinchu (TW)

(21) Appl. No.: 16/396,749

(22) Filed: Apr. 28, 2019

(51) Int. Cl. G01R 31/26; G01R 31/44

(52) U.S. Cl. CPC G01R 31/2635; G01R 31/2601; G01R 31/44

(57) ABSTRACT

A current driver array test apparatus is provided for testing a plurality of current drivers in an array, each of the current drivers provides a current when being activated. The current driver array test apparatus includes a plurality of test switches, a common test-enable pin, a common test-output pin, and a detector. One test switch is electrically coupled to one current driver. The common test-enable pin is coupled to each of the test switches. The common test-output pin is coupled to each of the test switches and receives the current. The detector is electrically coupled to the common test-output pin and receives the current from the common test-output pin. The number of the common test enable pin and the common test-output pin is only one. A current driver array test method and a micro light emitting diode array test method using the current driver array test apparatus are also provided.

### BACKGROUND

### Technical Field

The disclosure relates to a test apparatus, a test method, and a light emitting diode array test method, more specifically, to a current driver array test apparatus, a current driver array test method, and the micro light emitting diode array test method.

### Description of Related Art

The micro light emitting diode (micro-LED) array is driven by current drivers in one-to-one configuration. That is to say, each micro-LED in the array is driven by a current of the corresponding current driver. In addition, when fine pitch micro-LED is applied. The available area in the circuit is restricted, and flexibility in designing current drivers is also limited.

In the fine-pitch uLED design, currently it's impossible to use probes to probe the pad connected to the current driver in order to measure the current outputted from the current driver before bonding the micro-LEDs. After bonding the micro-LEDs on the array, there is no pad existed to test each digital pixel cell's bonding condition. One digital pixel cell includes one current driver and one micro-LED. Optical check for each micro-LED may be one alternative method, but the cost is really high. Therefore, a built-in test circuit for each digital pixel cell is needed before or after bonding.

However, in the built-in test circuit, either one test enable pin is shared and there are a plurality of test output pins or one test output pin is shared and there are a plurality of the test enable pins. Therefore, large routing resource and large area occupied by the built-in test circuit are required, which means large layout area, thereby being not suitable in the fine-pitch micro-LED design.

### SUMMARY

The disclosure is directed to a current driver array test apparatus with greatly reduced routing resource and layout area and suitable to be a built-in test circuit in the fine-pitch micro-LED array.

The disclosure is directed to a current driver array test method using the current driver array test apparatus.

The disclosure is directed to a micro light emitting diode array test method using the current driver array test apparatus.

The disclosure provides a current driver array test apparatus for testing a plurality of current drivers in an array, each of the plurality of current drivers is configured to provide a current when being activated. The current driver array test apparatus includes a plurality of test switches, a common test-enable pin, a common test-output pin, and a detector. Each of the test switches is electrically coupled to a corresponding one of the current drivers. The common test-enable pin is electrically coupled to each of the test switches to turn on or turn off each of the test switches. The common test-output pin is electrically coupled to each of the test switches and receives the current through each of the test switches from the corresponding one of the current drivers when the current drivers are activated one by one. The detector is electrically coupled to the common test-output pin and is configured to receive the current from the common test-output pin to determine whether a value of the current is in a predetermined range. The number of the common test enable pin is only one, and the number of the common test-output pin is only one.

In one embodiment of the disclosure, the common test-output pin receives the current through each of the plurality of test switches at different time.

In one embodiment of the disclosure, the test switch is a switching transistor.

In one embodiment of the disclosure, the test switch is a diode-connected transistor.

In one embodiment of the disclosure, the current driver array test apparatus further includes a first switch, a second switch, and a third switch. The first switch is electrically coupled between the common test-enable pin and a first voltage, the second switch is electrically coupled between the common test-enable pin and a second voltage, and the third switch is electrically coupled between the common test-enable pin and a third voltage.

In one embodiment of the disclosure, the third voltage is applied to the common test-output pin.

In one embodiment of the disclosure, the detector is a current sensing circuit, and the current sensing circuit is electrically connected between the common test-output pin and the first voltage.

The disclosure provides a current driver array test method for an array having a plurality of current drivers, each of the current drivers is configured to provide a current when being activated. The current driver array test method includes steps of providing a plurality of test switches, each of the test switches is electrically coupled to a corresponding one of the current drivers; providing a common test-enable pin, wherein the common test-enable pin is electrically coupled to each of the test switches to turn on or turn off each of the test switches; providing a common test-output pin, wherein the common test-output pin is electrically coupled to each of the test switches and receives the current through each of the test switches from the corresponding one of the current drivers when the current drivers are activated one by one; and providing a detector, wherein the detector is electrically coupled to the common test-output pin and configured to receive the current from the common test-output pin to determine whether a value of the current is in a predetermined range. The number of the common test enable pin is only one, and the number of the common test-output pin is only one.

In one embodiment of the disclosure, the current driver array test method further includes a step of providing a first switch, a second switch, and a third switch. The first switch is electrically coupled between the common test-enable pin and a first voltage, the second switch is electrically coupled between the common test-enable pin and a second voltage, and the third switch is electrically coupled between the common test-enable pin and a third voltage.

In one embodiment of the disclosure, the current driver array test method further includes steps of applying the first voltage to the common test-enable pin to turn on the plurality of test switches; activating and deactivating each of the plurality of current drivers one by one; and applying the second voltage to the common test-enable pin to turn off the plurality of test switches.

In one embodiment of the disclosure, the test switch is a switching transistor.

The disclosure provides a micro-LED array test method for a micro LED array having a plurality of current drivers and a plurality of micro light emitting devices, each of the plurality of current drivers is electrically connected to a corresponding one of the micro light emitting devices and is configured to provide a current when being activated. The micro-LED array test method includes steps of providing a plurality of test switches, each of the test switches is electrically coupled to a corresponding one of the current drivers; providing a common test-enable pin, wherein the common test-enable pin is electrically coupled to each of the test switches to turn on or turn off each of the test switches; providing a common test-output pin, wherein the common test-output pin is electrically coupled to each of the test switches and receives the current through each of the test switches from the corresponding one of the current drivers when the current drivers are activated one by one; and providing a detector, wherein the detector is electrically coupled to the common test-output pin and is configured to receive the current from the common test-output pin to determine whether a value of the current is in a predetermined range. The number of the common test enable pin is only one, and the number of the common test-output pin is only one.

In one embodiment of the disclosure, the micro-LED array test method further includes a step of providing a first switch, a second switch, and a third switch. The first switch is electrically coupled between the common test-enable pin and a first voltage, the second switch is electrically coupled between the common test-enable pin and a second voltage, and the third switch is electrically coupled between the common test-enable pin and a third voltage.

In one embodiment of the disclosure, the micro-LED array test method further includes steps of applying the third voltage to the common test enable pin to turn on the plurality of test switches; activating and deactivating each of the plurality of current drivers one by one; and applying the second voltage to the common test enable pin to turn off the plurality of test switches.

In one embodiment of the disclosure, the test switch is a diode-connected transistor.

In one embodiment of the disclosure, the detector is connected to the first voltage, and the voltage at a position among the activated current driver, the micro light emitting device corresponding to the activated current driver, and the test switch corresponding to the activated current driver is higher than a sum of the forward voltage of the micro light emitting device and the voltage of the common rail and is higher than a sum of the first voltage and a threshold voltage of the test switch.

Based on the above, in the disclosure, the number of the common test enable pin is only one, and the number of the common test-output pin is only one. That is to say, a plurality of test switches share the same common test enable pin and also share the same common test-output pin, thereby greatly reducing the routing resource and the layout area of the current driver array test apparatus. Consequently, the area occupied by the current driver array test apparatus is also greatly reduced. Therefore, the current driver array test apparatus is suitable to be a built-in test circuit for each digital pixel cell in the fine-pitch micro-LED array.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic view showing a row scanning process in a display according to one embodiment of the disclosure.

FIG. 2A and FIG. 2B are schematic views showing a digital pixel according to the embodiment in FIG. 1.

FIG. 3 is a schematic view showing a current driving digital pixel apparatus of a digital pixel cell according to one embodiment of the disclosure.

FIG. 4 is a schematic view showing a current driver array according to another embodiment of the disclosure.

FIG. 5 is a schematic view showing a current driver array test apparatus and a current driver array according to another embodiment of the disclosure.

FIG. 6A, FIG. 6B, and FIG. 6C are schematic views showing sequence of activating the current drivers in FIG. 5.

FIG. 7 is a schematic view showing a current driver array test apparatus while testing a current driver according to another embodiment of the disclosure.

FIG. 8 and FIG. 9 are flow charts showing a current driver array test method according to one embodiment of the disclosure.

FIG. 10 is a schematic view showing a current driver array test apparatus and a micro LED array according to another embodiment of the disclosure.

FIG. 11 is a flow chart showing a micro-LED array test method according to another embodiment of the disclosure.

### DESCRIPTION OF THE EMBODIMENTS

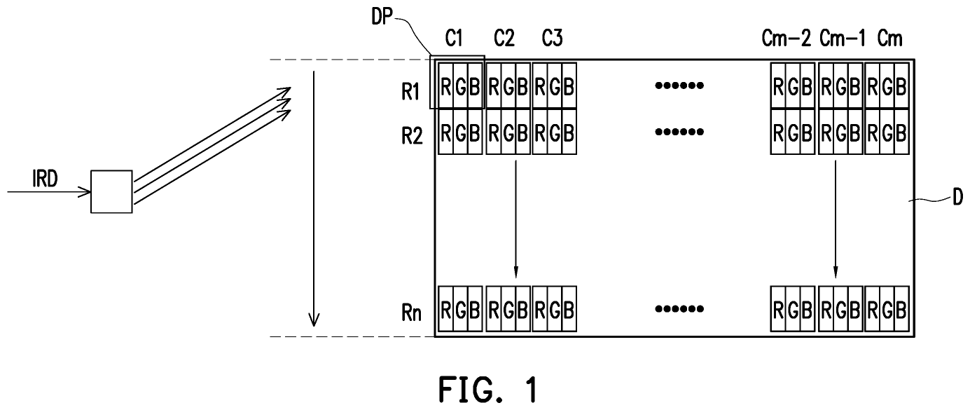

FIG. 1 is a schematic view showing a row scanning process in a display according to one embodiment of the disclosure. As shown in FIG. 1, a display D has a screen formed of an array of digital pixels DP. To be more specific, the screen of the display D has m columns C1 to Cm and n rows R1 to Rn of digital pixels DP, and m and n are integers greater than or equal to 1. Each of the digital pixels DP is constituted of one blue micro-LED, one green micro-LED, and one red micro-LED and the corresponding current drivers. In addition, each of the blue micro-LED, the green micro-LED, and the red micro-LED functions as a light source when receiving data from a controller (not shown). In the display D, an input row data IRD is provided to a single row of the digital pixels DP or to a plurality of rows of the digital pixels DP at a time. When receiving the input row data IRD, the blue micro-LEDs, the green micro-LEDs, and the red micro-LEDs in the single row or the plurality of rows emit blue light, green light, and red light so as to function as the light source at that time. Next, the input row data IRD is provided to the next row or next rows in sequence from R1 to Rn or in direction of the arrows from the top to the bottom of the display D as shown in FIG. 1. In other words, the light source, which is a single row or a plurality of rows of the digital pixels DP, scan vertically between the row R1 and the row Rn, and the input row data IRD is continuously inputted to control the rows of digital pixels DP to display image. In this way, the full screen of m×n digital pixels DP resolution is realized.

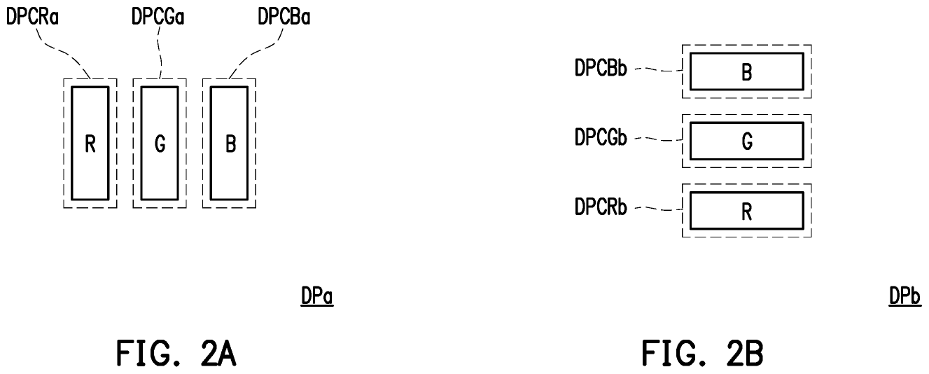

FIG. 2A and FIG. 2B are schematic views showing a digital pixel according to the embodiment in FIG. 1. As shown in FIG. 2A, a digital pixel DPa includes a red micro-LED R, a green micro-LED G, and a blue micro-LED B directly bonding on a silicon chip. To be more specific, each of the red micro-LED R, the green micro-LED G, and the blue micro-LED B is driven by one cell driver circuit (current driver) disposed below. The red micro-LED R and the corresponding cell driver circuit disposed under the red micro-LED R form a red digital pixel cell DPCRa. Similarly, the green micro-LED G and the corresponding cell driver circuit disposed under the green micro-LED G form a green digital pixel cell DPCGa, and the blue micro-LED B and the corresponding cell driver circuit disposed under the blue micro-LED B form a blue digital pixel cell DPCBa. In the present embodiment, the red digital pixel cell DPCRa, the green digital pixel cell DPCGa, and the blue digital pixel cell DPCBa are horizontally arranged, but the disclosure is not limited thereto.

A digital pixel DPb shown in FIG. 2B is similar to the digital pixel DPa shown in FIG. 2A. The difference is that a red digital pixel cell DPCRb, the green digital pixel cell DPCGb, and the blue digital pixel cell DPCBb are vertically arranged.

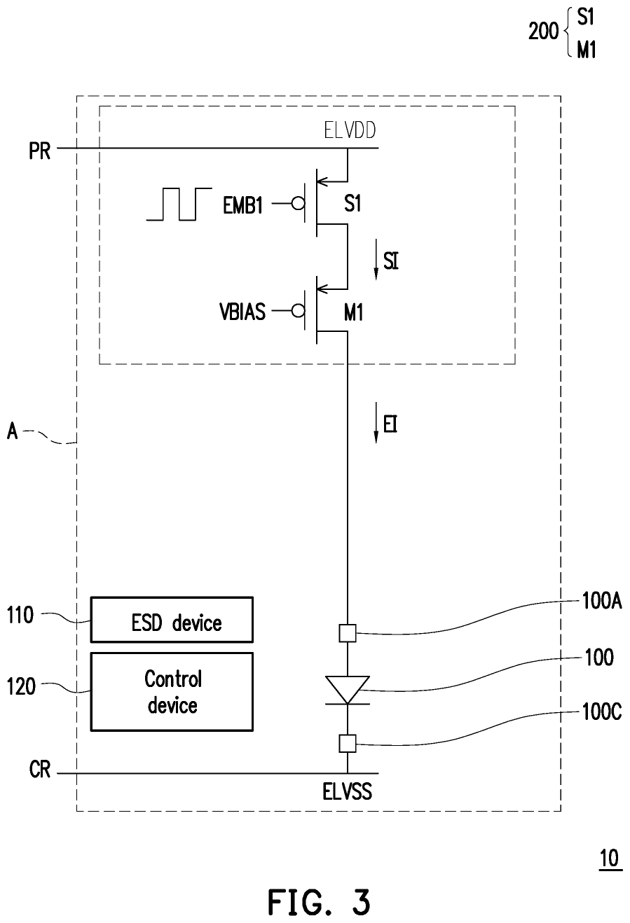

FIG. 3 is a schematic view showing a current driving digital pixel apparatus of a digital pixel cell according to one embodiment of the disclosure. As shown in FIG. 3, a current driving digital pixel apparatus 10 includes a power rail PR, a common rail CR, a micro light emitting device 100, and a current driver 200. The micro light emitting device 100 is electrically coupled to the common rail CR. The current driver 200 includes a switching device S1 and a current mirror device M1. The switching device S1 of the current driver 200 is electrically coupled to the power rail PR. The current mirror device M1 of the current driver 200 is electrically coupled between the switching device S1 and the micro light emitting device 100. To be more specific, an anode 100A of the micro light emitting device 100 is electrically connected to the current mirror device M1, and a cathode 100C of the micro light emitting device 100 is electrically connected to the common rail CR. The micro light emitting device 100 and the current driver 200 are both located in the same area A of the digital pixel cell in the current driving digital pixel apparatus 10.

The current driving digital pixel apparatus 10 further includes an electrostatic discharge device 110 and a control device 120. The electrostatic discharge device 110 is used to protect an internal circuit of the current driving digital pixel apparatus 10. The control device 120 is used to control the internal circuit of the current driving digital pixel apparatus 10. The electrostatic discharge device 110 and the control device 120 are arranged/located the same area A of the digital pixel cell in the current driving digital pixel apparatus 10.

In addition, the power rail PR is configured to supply a source current SI to the current mirror device M1 through the switching device S1, and the switching device S1 is configured to turn on and turn off the source current SI received by the current mirror device M1. The current mirror device M1 receives the source current SI from the power rail PR through the switching device S1 and supplies a current EI, which is an expected current, to the micro light emitting device 100.

When the micro light emitting device 100 is turned off or in a disable state, the voltage of the anode 100A of the micro light emitting device 100 is approximately equal to a voltage ELVSS of the common rail CR. Since the current mirror device M1 is directly and electrically connected to the anode 100A of the micro light emitting device 100, the current mirror device M1 should be a medium voltage (MV) device when concerning the stress of the current mirror device M1. In other words, the current mirror device M1 should be a medium voltage (MV) device to withstand the voltage stress from the anode 100A.

Since the switching device S1 is electrically coupled between the power rail PR and the current mirror device M1, the switching device S1 is near a voltage ELVDD of the power rail PR. Therefore, when the switching device S1 is turned on (in enable state) or is turned off (in disable state), the drain, the source, the gate, and the buck of the switching device S1 are not stressed because of overvoltage. Consequently, it is possible that the switching device S1 is a low voltage (LV) device. It should be noted here, the switching device S1 is configured to turn on and turn off the source current SI received by the current mirror device M1.

As a result, in the present embodiment, the switching device S1 is a LV device and the current mirror device M1 is a MV device. In addition, the switching device S1 is controlled to be turned on or turned off by the high and low levels of a signal EMB1, and the current mirror device M1 is controlled by a voltage signal VBIAS. Since the switching device S1 is a LV device, it is possible that the signal EMB1 is a LV lever control signal, and the waveform of the signal EMB1 is shown in FIG. 3 as an example. It should be noted here, the signal EMB1 and the voltage signal VBIAS may be applied at the same time or at different times, the disclosure is not limited thereto.

Normally, the LV device has a lower threshold voltage Vt, a lower turn-on resistance, and a smaller size compared to the MV device. Therefore, in the present embodiment, the dynamic power required in turning on and turning off the switching device S1, which is a LV device, is reduced. In addition, the coupling back noise from the switching device S1, when switching (turning on and turning off), to the voltage signal VBIAS is also greatly reduced.

In the present embodiment, the switching device S1 is a switching transistor, and the current mirror device M1 is a current mirror transistor circuit. The micro light emitting device 100 may be a red, green, or blue micro-LED. However, the disclosure is not limited thereto.

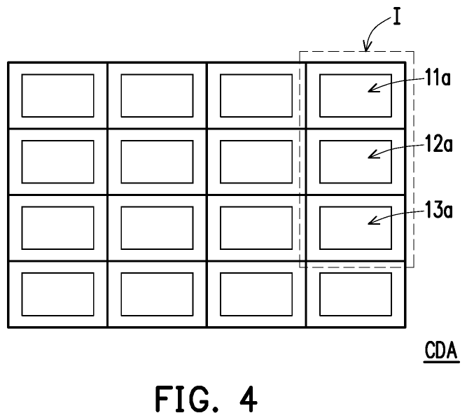

FIG. 4 is a schematic view showing a current driver array according to another embodiment of the disclosure. In the manufacturing process of the screen having the array of digital pixels DP, a current driver array CDA is manufactured first without bonding the micro light emitting devices. It is called “before bonding”. To be more specific, in the present embodiment shown in FIG. 4, the current driver array CDA has 4 columns and 4 rows of current drivers as an example. In the disclosure, the current driver array may have m columns and n rows of current drivers, and m and n are integers greater than or equal to 1. Each current driver belongs to a current driving digital pixel apparatus, as mentioned above. As shown in FIG. 4, a region I including three current driving digital pixel apparatuses 11a, 12a, and 13a is used for demonstration hereinafter. However, the disclosure is not limited thereto.

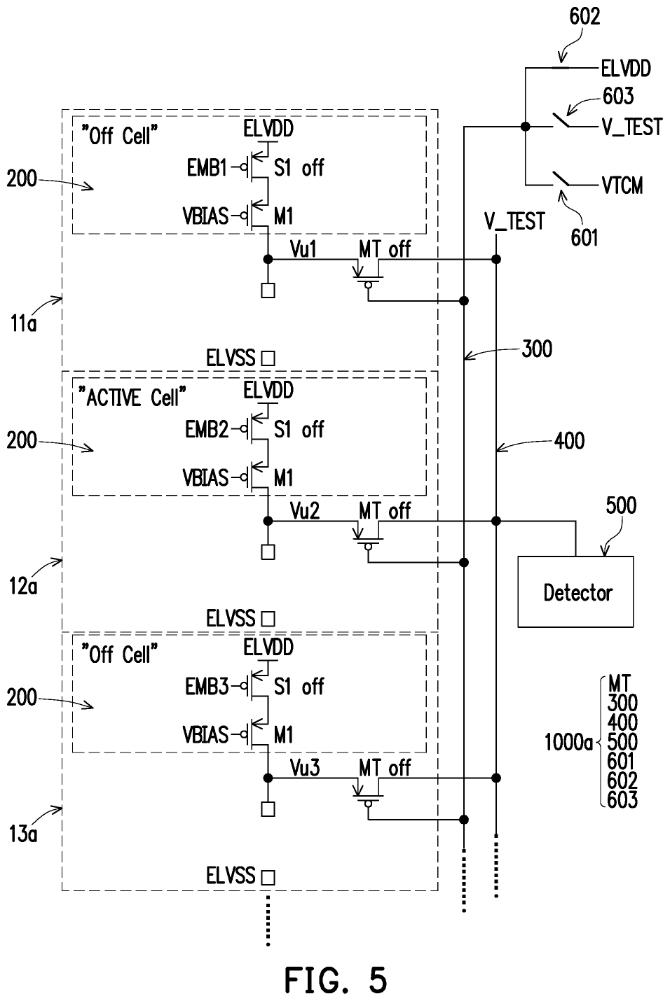

FIG. 5 is a schematic view showing a current driver array test apparatus and a current driver array according to another embodiment of the disclosure. In FIG. 5, three current driving digital pixel apparatuses 11a, 12a, and 13a of the region I which are before bonding are shown. That is to say, the difference between each of the current driving digital pixel apparatuses 11a, 12a, and 13a and the current driving digital pixel apparatus 10 in FIG. 3 is that each of the current driving digital pixel apparatuses 11a, 12a, and 13a does not include the micro light emitting device 100, or the micro light emitting device 100 is not bonded in each of the current driving digital pixel apparatuses 11a, 12a, and 13a yet. In addition, the current driver array includes the current drivers 200 of the current driving digital pixel apparatuses 11a, 12a, and 13a. At this stage, it is required to test the current provided by the current driver 200 in each of the current driving digital pixel apparatuses 11a, 12a, and 13a.

In the present embodiment, the current provided by the current driver 200 in each of the current driving digital pixel apparatuses 11a, 12a, and 13a is tested by a current driver array test apparatus 1000a, as shown in FIG. 5. The current driver array test apparatus 1000a includes a plurality of test switches MT, a common test-enable pin 300, a common test-output pin 400, and a detector 500. Each of the test switches MT is electrically coupled to a corresponding one of the current drivers 200 of the current driving digital pixel apparatuses 11a, 12a, and 13a. That is to say, each of the current drivers 200 is electrically coupled to one test switch MT. The common test-enable pin 300 is electrically coupled to each of the test switches MT to turn on or turn off each of the test switches MT. The common test-output pin 400 is electrically coupled to each of the test switches MT. In addition, the common test-output pin 400 receives the current through each of the test switches MT from the corresponding one of the current drivers 200 when the current drivers 200 are activated one by one. In addition, the current drivers 200 are sequentially activated one by one as described as follows.

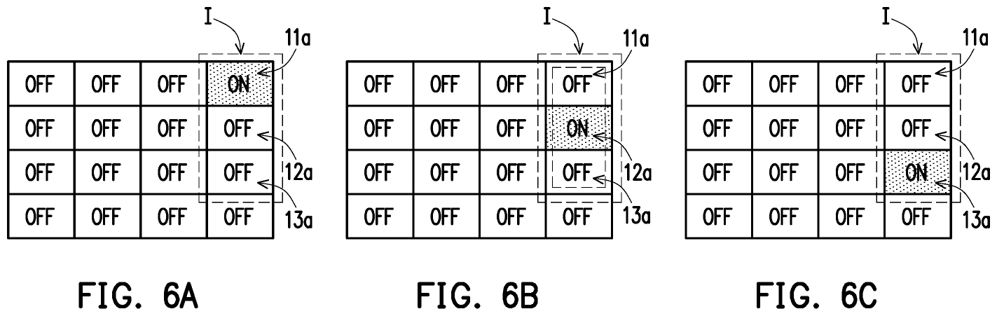

FIG. 6A, FIG. 6B, and FIG. 6C are schematic views showing sequence of activating the current drivers in FIG. 5. Referring to FIG. 5 and FIGS. 6A to 6C simultaneously, in the present embodiment, when the current driver 200 of the current driving digital pixel apparatus 11a is activated or ON for a period of time as shown in FIG. 6A, the switching device S1 of the current driving digital pixel apparatus 11a is turned on for a period of time, and the current driver 200 of the current driving digital pixel apparatus 11a provides a current through the corresponding test switch MT to the common test-output pin 400. After that, the current driver 200 of the current driving digital pixel apparatus 11a is deactivated of OFF by tuning off the switching device S1, and the current driver 200 of the current driving digital pixel apparatus 12a is activated or ON for a period of time as shown in FIG. 6B. At this time, the switching device S1 of the current driving digital pixel apparatus 12a is turned on for a period of time, and the current driver 200 of the current driving digital pixel apparatus 12a provides a current through the corresponding test switch MT to the common test-output pin 400. Further, the current driver 200 of the current driving digital pixel apparatus 12a is deactivated or OFF by tuning off the switching device S1, and the current driver 200 of the current driving digital pixel apparatus 13a is activated or ON for a period of time as shown in FIG. 6C. While the current driver 200 of the current driving digital pixel apparatus 13a is activated, the switching device S1 of the current driving digital pixel apparatus 13a is turned on, and the current driver 200 of the current driving digital pixel apparatus 13a provides a current through the corresponding test switch MT to the common test-output pin 400. That is to say, at the same time, the common test-output pin 300 receives the current through only one of the test switches MT from the corresponding one of the current drivers 200, which is activated, of the current driving digital pixel apparatuses 11a, 12a, and 13a. In other words, the common test-output pin 400 receives the current through each of the test switches MT at different time.

Returning to FIG. 5, the a detector 500 is electrically coupled to the common test-output pin 400 and the detector 500 is configured to receive the current from the common test-output pin 400 to determine whether a value of the current is in a predetermined range. If the value of the current provided by one current driver 200 is in the predetermined range, that current driver 200 is normal without defect. In the present embodiment, the detector 500 may be a current sensing circuit including a resistor, the test switch MT may be a switching transistor or a diode-connected transistor.

It is emphasized here, the number of the common test enable pin 300 is only one, and the number of the common test-output pin 400 is only one. That is to say, a plurality of test switches MT share the same common test enable pin 300 and also share the same common test-output pin 400, thereby greatly reducing the routing resource and the layout area of the current driver array test apparatus. Consequently, the area occupied by the current driver array test apparatus is also greatly reduced. Therefore, the current driver array test apparatus is suitable to be a built-in test circuit for each digital pixel cell in the fine-pitch micro-LED array.

As further shown in FIG. 5, the current driver array test apparatus 1000a further includes a first switch 601, a second switch 602, and a third switch 603. The first switch 601 is electrically coupled between the common test-enable pin 300 and a voltage VTCM, which is the first voltage. The second switch 602 is electrically coupled between the common test-enable pin 300 and the voltage ELVDD, which is the second voltage. The third switch 603 is electrically coupled between the common test-enable pin 300 and a voltage V_TEST, which is the third voltage. When the first switch 601 is on, the first voltage VTCM is applied to the common test-enable pin 300, so as to turn on the test switches MT. When the second switch 602 is on, the second voltage ELVDD is applied to the common test-enable pin 300, so as to turn off the test switches MT. When the third switch 603 is on and the third voltage V_TEST is applied to the common test-enable pin 300, so as to turn on the test switches MT. In the present embodiment, the third voltage V_TEST is applied to the common test-output pin 400.

Further, voltages Vu1, Vu2, and Vu3 are the voltages between the test switches MT and the corresponding one of the current drivers 200 of the current driving digital pixel apparatuses 11a, 12a, and 13a. To be more specific, the voltage Vu1 is the voltage between the current driver 200 of the current driving digital pixel apparatus 11a and the corresponding test switch MT. The voltage Vu2 is the voltage between the current driver 200 of the current driving digital pixel apparatus 12a and the corresponding test switch MT. The voltage Vu3 is the voltage between the current driver 200 of the current driving digital pixel apparatus 13a and the corresponding test switch MT.

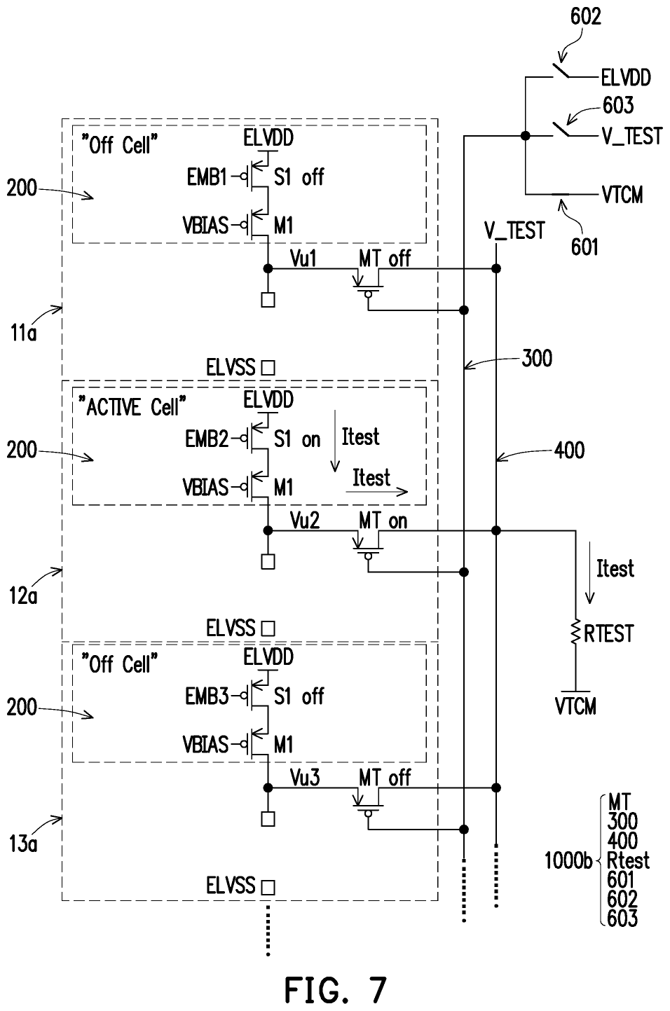

FIG. 7 is a schematic view showing a current driver array test apparatus while testing a current driver according to another embodiment of the disclosure. In the present embodiment is similar to the embodiment in FIG. 5, only the differences are described hereinafter. In the present embodiment, the detector 500 is implemented as a current sensing circuit including resistor Rtest, and the resistor Rtest is electrically connected between the common test-output pin 400 and the first voltage VTCM. That is to say, the difference between a current driver array test apparatus 1000b in the present embodiment and the current driver array test apparatus 1000a in FIG. 5 is that the current driver array test apparatus 1000b includes the resistor Rtest instead of the detector 500. As shown in FIG. 7, the first switch 601 is on, the first voltage VTCM is applied to the common test-enable pin 300, so as to turn on the test switches MT, and the current driver 200 of the current driving digital pixel apparatus 12a is activated. Since the test switch MT corresponding to the current driver 200 of the current driving digital pixel apparatus 12a is on, the current Itest provided from the current driver 200 of the current driving digital pixel apparatus 12a goes through that test switch MT, the common test-output pin 400, the resistor Rtest to the voltage VTCM. Therefore, the current Itest can be measured. For example, the current Itest can be measured according to the value of the resistor Rtest and the voltage difference between two ends of the resistor Rtest. That is to say, the current driver 200 of the current driving digital pixel apparatus 12a is tested. Further, the test switch MT is a switching transistor, and the voltage Vu2 is equal to the sum of the voltage VTCM, the voltage of the resistor ITEST*RTEST, and the source drain voltage Vds_MT of the test switch MT.

It should be noted here, all of the test switches MT are initially turned on when the first voltage VTCM is applied to the common test-enable pin 300. However, since the current drivers 200 of the current driving digital pixel apparatuses 11a and 13a are deactivated, the voltages Vu1 and Vu3 are discharged via the test switches MT until the test switches MT corresponding to the current drivers 200 of the current driving digital pixel apparatuses 11a and 13a are turned off, automatically. Further, the current drivers 200 of the current driving digital pixel apparatuses 11a and 13a are tested in the same manner with the current driver 200 of the current driving digital pixel apparatus 12a.

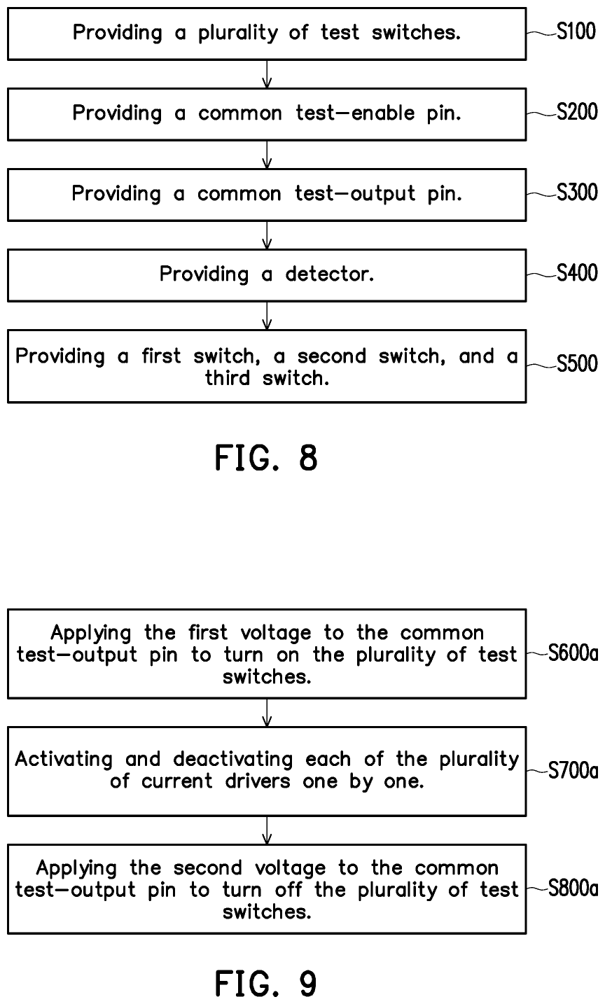

FIG. 8 and FIG. 9 are flow charts showing a current driver array test method according to one embodiment of the disclosure. Referring to FIG. 8 and FIG. 5, at the step S100, a plurality of test switches MT are provided, and each of the plurality of test switches MT is electrically coupled to a corresponding one of the plurality of current drivers 200 of the current driving digital pixel apparatuses 11a, 12a, and 13a. Next, in the step S200, a common test-enable pin 300 is provided, and the common test-enable pin 300 is electrically coupled to each of the plurality of test switches MT to turn on or turn off each of the plurality of test switches MT. In the step S300, a common test-output pin 400 is provided, the common test-output pin 400 is electrically coupled to each of the plurality of the test switches MT and receives the current through each of the plurality of test switches MT from the corresponding one of the plurality of current drivers 200 of the current driving digital pixel apparatuses 11a, 12a, and 13a when the plurality of current drivers 200 of the current driving digital pixel apparatuses 11a, 12a, and 13a are activated one by one, as shown in FIGS. 6A to 6C. In the step S400, a detector 500 is provided, and the detector 500 is electrically coupled to the common test-output pin 400 and is configured to receive the current from the common test-output pin 400 to determine whether a value of the current is in a predetermined range. It is emphasized here, the number of the common test enable pin 300 is only one, and the number of the common test-output pin 400 is only one.

Further, in step S500, a first switch 601, a second switch 602, and a third switch 603 are provided. The first switch 601 is electrically coupled between the common test-enable pin 300 and the first voltage VTCM. The second switch 602 is electrically coupled between the common test-enable pin 300 and the second voltage ELVDD. The third switch 603 is electrically coupled between the common test-enable pin 300 and the third voltage V_TEST. The third voltage V_TEST is applied to the common test-output pin 400.

Next, as shown in FIG. 9, in step S600a, the first voltage VTCM is applied to the common test-enable pin 300 to turn on the plurality of test switches MT corresponding to the current drivers 200 of the current driving digital pixel apparatuses 11a, 12a, and 13a. It should be noted here, the first switch 601 is turned on to apply the first voltage VTCM to the common test-enable pin 300. In step S700a, each of the current drivers 200 of the current driving digital pixel apparatuses 11a, 12a, and 13a is activated and then deactivated one by one, as shown in FIGS. 6A to 6C. Therefore, each of the current drivers 200 of the current driving digital pixel apparatuses 11a, 12a, and 13a is tested. In step S800a, the second voltage ELVDD is applied to the common test-enable pin 300 to turn off the plurality of test switches MT. The current driver array test method is finished.

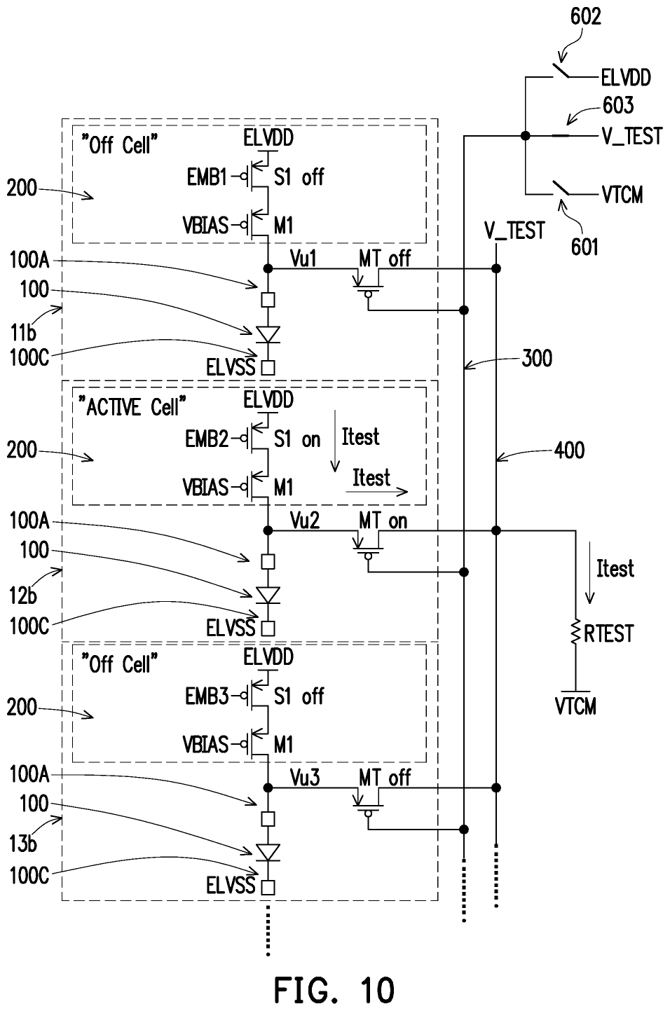

FIG. 10 is a schematic view showing a current driver array test apparatus and a micro LED array according to another embodiment of the disclosure. The present embodiment is similar to the embodiment in FIG. 7, only the differences are described hereinafter. In the present embodiment, each of the current driving digital pixel apparatuses 11b, 12b, and 13b includes the micro light emitting device 100. In other words, the micro light emitting device 100 is bonded to the current driver 200 in each of the current driving digital pixel apparatuses 11b, 12b, and 13b. It is called “after bonding”. Further, in the present embodiment, the third switch 603 is turned on to apply the third voltage V_TEST to the common test-enable pin 300 to turn on the test switches MT. Each of the test switches MT is a diode-connected transistor. The current driver 200 of the current driving digital pixel apparatus 12b is activated. The voltage at a position among the current driver 200, the micro light emitting device 100, and the test switch MT is a voltage Vu2. The voltage Vu2 is greater/higher than the sum of the forward voltage Vf of the micro light emitting device 100 and the voltage ELVSS of the common rail CR, which is the voltage of the cathode 100C of the micro light emitting device 100. In addition, the voltage Vu2 is greater/higher than the sum of the voltage VTCM and the threshold voltage Vt of the test switch MT. Therefore, a part of the current provided from the current driver 200 of the current driving digital pixel apparatus 12b flows through the micro light emitting device 100 to the voltage ELVSS. In addition, the other part, which is the current Itest shown in FIG. 10, of the current provided from the current driver 200 of the current driving digital pixel apparatus 12b flows through the test switch MT, the common test-output pin 400, the resistor Rtest to the voltage VTCM. Therefore, the current Itest can be measured and then is determined whether to be a predetermined range or not. It should be noted here, the micro light emitting device 100 in the current driving digital pixel apparatus 12b is turned on. In the case that the bonding of the micro light emitting device 100 in the current driving digital pixel apparatus 12b is good and qualified, the value of the current Itest is in the predetermined range. In the case that the bonding of the micro light emitting device 100 in the current driving digital pixel apparatus 12b is open, all of the current provided from the current driver 200 flows to the resistor Rtest. Therefore, the value of the current Itest is too high and is not in the predetermined range. In the case that the bonding of the micro light emitting device 100 in the current driving digital pixel apparatus 12b is short (short circuit), all of the current provided from the current driver 200 flows to the micro light emitting device 100. Therefore, the value of the current Itest is too low and is not in the predetermined range. As a result, the quality of bonding the micro light emitting device 100 in the current driving digital pixel apparatus 12b is determined.

It should be noted here, all of the test switches MT are initially turned on when the third voltage V_TEST is applied to the common test-enable pin 300. However, since the current drivers 200 of the current driving digital pixel apparatuses 11b and 13b are deactivated, the voltages Vu1 and Vu3 are discharged to be close to the voltage ELVSS of the common rail CR. Since each of the voltages Vu1 and Vu3 is much lower than the sum of the voltage VTCM and the threshold voltage Vt of the test switch MT, the test switches MT corresponding to the current drivers 200 of the current driving digital pixel apparatuses 11b and 13b are turned off, automatically. Further, the current drivers 200 of the current driving digital pixel apparatuses 11b and 13b are tested in the same manner with the current driver 200 of the current driving digital pixel apparatus 12b.

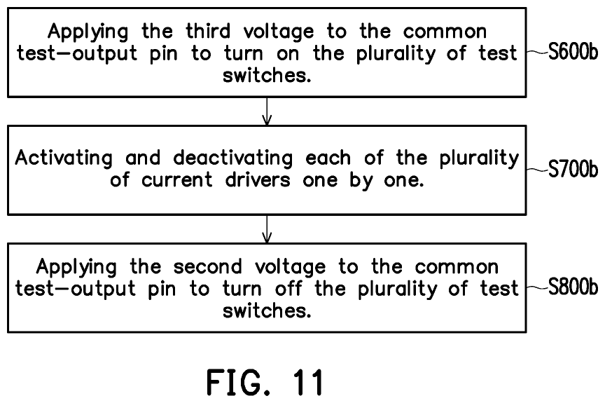

A micro light emitting diode (LED) array test method is provided in the disclosure. The micro-LED array test method includes steps S100 to S500 shown in FIG. 8. However, the micro-LED array test method further includes different steps. FIG. 11 is a flow chart showing a micro-LED array test method according to another embodiment of the disclosure. As shown in FIG. 11, the micro-LED array test method further includes step S600b, step S700b, and S800b. in step S600b, the third voltage V_TEST is applied to the common test enable pin 300 to turn on the test switches MT corresponding to the current drivers 200 of the current driving digital pixel apparatuses 11b, 12b, and 13b. In addition, in step S700b, each of the current drivers 200 of the current driving digital pixel apparatuses 11b, 12b, and 13b is activated and then deactivated one by one. Further, in step S800b, the second voltage ELVDD is applied to the common test-enable pin 300 to turn off the plurality of test switches MT. The micro-LED array test method is finished.

In summary, in the disclosure, the number of the common test enable pin is only one, and the number of the common test-output pin is only one. That is to say, a plurality of test switches share the same common test enable pin and also share the same common test-output pin, thereby greatly reducing the routing resource and the layout area of the current driver array test apparatus. Consequently, the area occupied by the current driver array test apparatus is also greatly reduced. Therefore, the current driver array test apparatus is suitable to be a built-in test circuit for each digital pixel cell in the fine-pitch micro-LED array.

Further, in the disclosure, the voltage at a position among the current driver, the micro light emitting device, and the test switch in the activated current driving digital pixel apparatus is greater/higher than the sum of the forward voltage of the micro light emitting device and the voltage of the common rail and is also greater/higher than the sum of the first voltage and the threshold voltage of the test switch. Hence, the current provided from the current driver of the activated current driving digital pixel apparatus partially flows to the micro light emitting device and also partially flows to the resistor. Based on the part of current flowing to the resistor, the quality of bonding the micro light emitting device in the current driving digital pixel apparatus is determined.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A current driver array test apparatus for testing a plurality of current drivers in an array, each of the plurality of current drivers being configured to provide a current when being activated, the current driver array test apparatus comprising:
a plurality of test switches, each of the plurality of test switches being electrically coupled to a corresponding one of the plurality of current drivers;
a common test-enable pin, electrically coupled to each of the plurality of test switches to turn on or turn off each of the plurality of test switches;
a common test-output pin, electrically coupled to each of the plurality of test switches and receiving the current through each of the plurality of test switches from the corresponding one of the plurality of current drivers when the plurality of current drivers are activated one by one; and
a detector, electrically coupled to the common test-output pin and configured to receive the current from the common test-output pin to determine whether a value of the current is in a predetermined range,
wherein a number of the common test enable pin is only one, and a number of the common test-output pin is only one.

2. The current driver array test apparatus as recited in claim 1, wherein the common test-output pin receives the current through each of the plurality of test switches at different time.

3. The current driver array test apparatus as recited in claim 1, wherein the test switch is a switching transistor.

4. The current driver array test apparatus as recited in claim 1, wherein the test switch is a diode-connected transistor.

5. The current driver array test apparatus as recited in claim 1, further comprising a first switch, a second switch, and a third switch, wherein the first switch is electrically coupled between the common test-enable pin and a first voltage, the second switch is electrically coupled between the common test-enable pin and a second voltage, and the third switch is electrically coupled between the common test-enable pin and a third voltage.

6. The current driver array test apparatus as recited in claim 5, wherein the third voltage is applied to the common test-output pin.

7. The current driver array test apparatus as recited in claim 5, wherein the detector is a current sensing circuit, and the current sensing circuit is electrically connected between the common test-output pin and the first voltage.

8. A current driver array test method for an array having a plurality of current drivers, each of the plurality of current drivers being configured to provide a current when being activated, the current driver array test method comprising:
providing a plurality of test switches, each of the plurality of test switches being electrically coupled to a corresponding one of the plurality of current drivers;
providing a common test-enable pin, wherein the common test-enable pin is electrically coupled to each of the plurality of test switches to turn on or turn off each of the plurality of test switches;
providing a common test-output pin, wherein the common test-output pin is electrically coupled to each of the plurality of the test switches and receives the current through each of the plurality of test switches from the corresponding one of the plurality of current drivers when the plurality of current drivers are activated one by one; and
providing a detector, wherein the detector is electrically coupled to the common test-output pin and configured to receive the current from the common test-output pin to determine whether a value of the current is in a predetermined range,
wherein a number of the common test enable pin is only one, and a number of the common test-output pin is only one.

9. The current driver array test method as recited in claim 8, further comprising:
providing a first switch, a second switch, and a third switch, wherein the first switch is electrically coupled between the common test-enable pin and a first voltage, the second switch is electrically coupled between the common test-enable pin and a second voltage, and the third switch is electrically coupled between the common test-enable pin and a third voltage.

10. The current driver array test method as recited in the claim 9, further comprising:
applying the first voltage to the common test-enable pin to turn on the plurality of test switches;
activating and deactivating each of the plurality of current drivers one by one; and
applying the second voltage to the common test-enable pin to turn off the plurality of test switches.

11. The current driver array test method as recited in claim 8, wherein the test switch is a switching transistor.

12. A micro light emitting diode (micro-LED) array test method for a micro-LED array having a plurality of current drivers and a plurality of micro light emitting devices, each of the plurality of current drivers being electrically connected to a corresponding one of the plurality of micro light emitting devices and being configured to provide a current when being activated, the micro-LED array test method comprising:
providing a plurality of test switches, each of the plurality of test switches being electrically coupled to a corresponding one of the plurality of current drivers;
providing a common test-enable pin, wherein the common test-enable pin is electrically coupled to each of the plurality of test switches to turn on or turn off each of the plurality of test switches;
providing a common test-output pin, wherein the common test-output pin is electrically coupled to each of the plurality of test switches and receives the current through each of the plurality of test switches from the corresponding one of the plurality of current drivers when the plurality of current drivers are activated one by one; and
providing a detector, wherein the detector is electrically coupled to the common test-output pin and configured to receive the current from the common test-output pin to determine whether a value of the current is in a predetermined range,
wherein a number of the common test enable pin is only one, and a number of the common test-output pin is only one.

13. The micro-LED array test method as recited in claim 12, further comprising:
providing a first switch, a second switch, and a third switch, wherein the first switch is electrically coupled between the common test-enable pin and a first voltage, the second switch is electrically coupled between the common test-enable pin and a second voltage, and the third switch is electrically coupled between the common test-enable pin and a third voltage.

14. The micro-LED array test method as recited in claim 13, further comprising:
applying the third voltage to the common test enable pin to turn on the plurality of test switches;
activating and deactivating each of the plurality of current drivers one by one; and
applying the second voltage to the common test enable pin to turn off the plurality of test switches.

15. The micro-LED array test method as recited in claim 12, wherein the test switch is a diode-connected transistor.

16. The micro-LED array test method as recited in claim 14, wherein the detector is connected to the first voltage, and a voltage at a position among the activated current driver, the micro light emitting device corresponding to the activated current driver, and the test switch corresponding to the activated current driver is higher than a sum of the forward voltage of the micro light emitting device and the voltage of the common rail and is higher than a sum of the first voltage and a threshold voltage of the test switch.
